(19) United States
(12) Patent Application Publication
(10) Pub. No.: US 2023/0217637 A1
(43) Pub. Date: Jul. 6, 2023

(54) COMPONENT MOUNTING SYSTEM

(71) Applicant: FUJI CORPORATION, Chiryu (JP)

(72) Inventor: Hidetoshi KAWAI, Anjo-shi (JP)

(73) Assignee: FUJI CORPORATION, Chiryu (JP)

(21) Appl. No.: 18/000,839

(22) PCT Filed: Jun. 29, 2020
(86) PCT No.: PCT/JP2020/025499

§ 371 Date: Dec. 6, 2022

(51) Int. Cl. H05K 13/08; H05K 13/04

(52) U.S. Cl. CPC H05K 13/0812; H05K 13/083; H05K 13/0495; H05K 13/046

(57) ABSTRACT

A component mounting system includes a mounting machine configured to perform a mounting process of a component on a board by an operation of a unit for the mounting process, an inspector configured to perform an inspection process by using an image of the board after the mounting process and output abnormality information capable of specifying a defective board having an abnormality detected in the inspection process, a camera configured to image the operation of the unit in the mounting machine during the mounting process in a video to store image data in a memory, and a data output section configured to extract image data during the mounting process of the defective board from the memory based on the abnormality information and output the image data to an outside.

### TECHNICAL FIELD

The present specification discloses a component mounting system.

### BACKGROUND ART

Conventionally, as a component mounting system of this type, there has been proposed a component mounting system including a mounting machine that collects components such as electronic components and performs a mounting process for mounting the components on a target object such as a printed circuit board, and an inspector that inspects a mounting state by the mounting machine (for example, refer to Patent Literature 1). In this system, when an abnormality is detected in an inspection by the inspector, gist thereof is stored as performance information or displayed on a terminal of an operator.

### PATENT LITERATURE

Patent Literature 1: JP-A-2019-201144

### SUMMARY OF THE INVENTION

### Technical Problem

Here, when there is an abnormality in a mounting state, a cause of abnormality is required to be specified and appropriately coped with the abnormality. However, when an inspector detects an abnormality although the mounting machine has performed a mounting process as usual, the mounting machine may have overlooked the abnormality, and thus, it is difficult for an operator to specify the cause of abnormality. In addition, although it is also considered to install a monitoring camera in a mounting machine and investigate a cause of abnormality from an image of the monitoring camera, an operator has to check and analyze all images captured during a mounting process, and thus, many man-hours are required.

A main object of the present disclosure is to enable easy investigation of a cause of abnormality from image data during a mounting process.

### Solution to Problem

The present disclosure employs the following means in order to achieve the above-described main object.

A component mounting system of the present disclosure includes a mounting machine configured to perform a mounting process of a component on a board by an operation of a unit for the mounting process, an inspector configured to perform an inspection process by using an image of the board after the mounting process and output abnormality information capable of specifying a defective board having an abnormality detected in the inspection process, a camera configured to image the operation of the unit in the mounting machine during the mounting process in a video to store image data in a memory, and a data output section configured to extract image data during the mounting process of the defective board from the memory based on the abnormality information and output the image data to an outside.

The component mounting system of the present disclosure includes a camera that images an operation of a unit in a mounting machine during a mounting process in a video and stores image data in a memory, and extracts image data during a mounting process of a defective board from the image data in the memory based on abnormality information (inspection abnormality information) output from an inspector when an abnormality is detected in an inspection process, and outputs the image data to the outside. Accordingly, it is possible to reduce labor for an operator or the like to check all image data in a memory and search the image data during a mounting process of a defective board from a memory. Therefore, a cause of abnormality can be easily investigated from image data during a mounting process of a defective board.

### BRIEF DESCRIPTION OF DRAWINGS

FIG. 1 is an explanatory view illustrating an example of component mounting system 10.

FIG. 2 is a configuration view illustrating a schematic configuration of mounting machine 20.

FIG. 3 is an explanatory view illustrating an electrical connection relationship among mounting machine 20, mounting inspector 30, and management device 40.

FIG. 4 is an explanatory view illustrating a capacity of memory 27m of built-in camera 27 provided in each mounting machine 20.

FIG. 5 is a flowchart illustrating an example of a board inspection process.

FIG. 6 is a flowchart illustrating an example of an image data output process.

FIG. 7 is an explanatory view illustrating a state in which image data is output from each built-in camera 27.

FIG. 8 is an explanatory view illustrating a state in which image data is output from each built-in camera 27.

### DESCRIPTION OF EMBODIMENTS

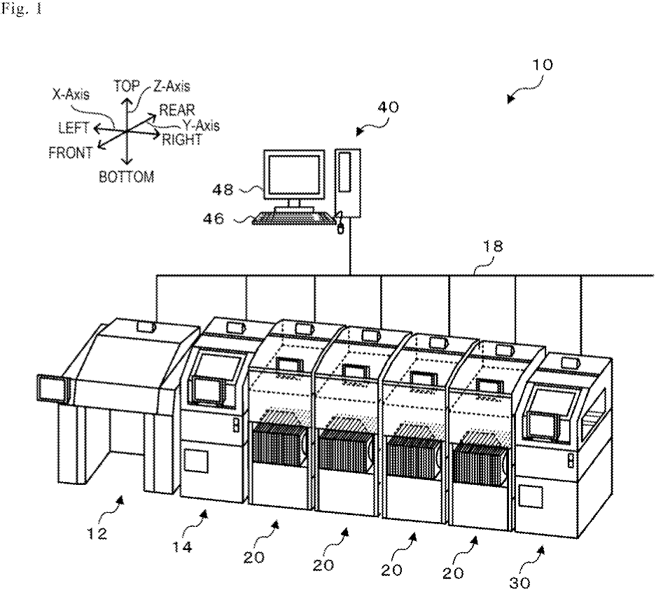

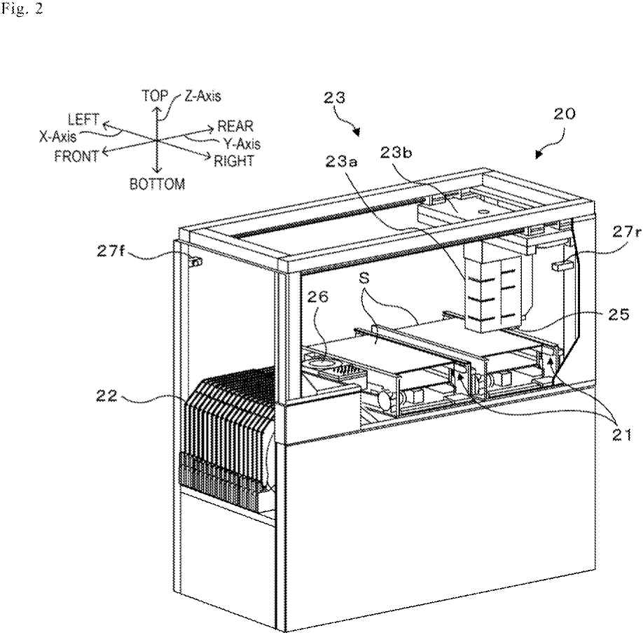

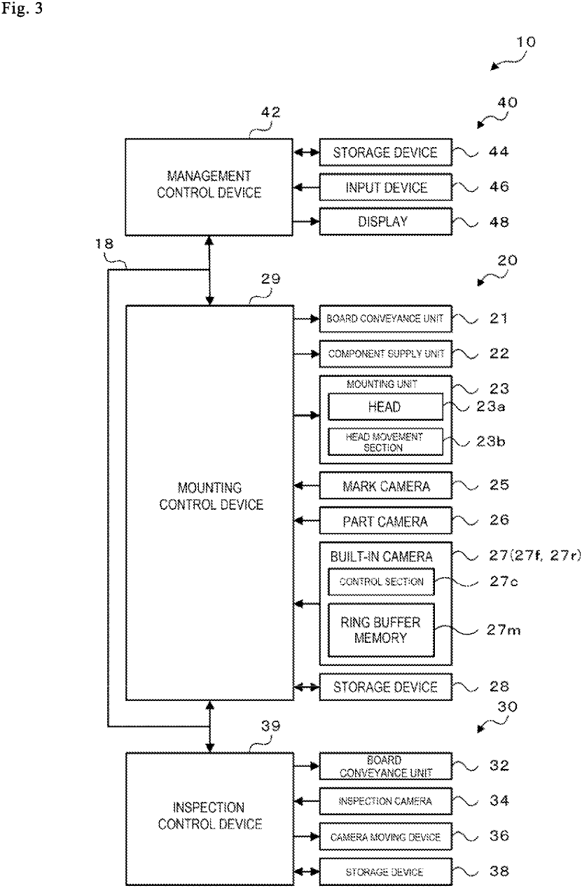

Embodiments of the present disclosure will be described with reference to the drawings. FIG. 1 is a configuration view illustrating a schematic configuration of component mounting system 10, FIG. 2 is a configuration view illustrating a schematic configuration of mounting machine 20, and FIG. 3 is an explanatory diagram illustrating an electrical connection relationship among mounting machine 20, mounting inspector 30, and management device 40. In FIGS. 1 and 2, a left-right direction is an X direction, a front-rear direction is a Y direction, and an up-down direction is a Z direction.

As illustrated in FIG. 1, component mounting system 10 includes printer 12, print inspector 14, multiple mounting machines 20, mounting inspector 30, and management device 40, which are connected to LAN 18 serving as a network. Printer 12 prints on boards S (refer to FIG. 2) by pushing solder into pattern holes formed in a screen mask. Print inspector 14 inspects a state of the solder printed by printer 12. Mounting machines 20 are arranged along a conveyance direction (the X direction) of boards S, and sequentially deliver boards S to perform a mounting process of components on boards S. Mounting inspector 30 inspects mounting states of the components mounted on boards S by each mounting machine 20. Management device 40 manages entirety of component mounting system 10. Printer 12, print inspector 14, multiple mounting machines 20, and mounting inspector 30 are arranged in this order in the conveyance direction of boards S to configure a production line. In addition to this, the production line includes a reflow device or the like that performs a reflow process of the boards S on which components are mounted, and the reflow device is disposed on, for example, a downstream side of mounting inspector 30. A reflow inspector may be disposed on a downstream side of the reflow device.

As illustrated in FIGS. 2 and 3, mounting machine 20 includes a board conveyance unit 21, component supply unit 22, and mounting unit 23. Board conveyance unit 21 has two pairs of conveyor belts that are stretched in the left-right direction at intervals in the front and rear of FIG. 2, and each conveyor belt conveys boards S from the left to the right in the drawing. Component supply unit 22 is, for example, a tape feeder that supplies components by feeding a tape in which components are accommodated at a predetermined pitch, and is configured in multiple sets in mounting machine 20 so as to be able to supply multiple types of components. Mounting unit 23 includes head 23a in which nozzles for picking up components are arranged to be able to move up and down, and head movement section 23b for moving head 23a in XY-directions.

In addition, mounting machine 20 includes mark camera 25, part camera 26, built-in camera 27, storage device 28, and mounting control device 29 that controls entirety of mounting machine 20. Mark camera 25 is attached to head 23a and is moved in the XY-directions together with head 23a by head movement section 23b. Mark camera 25 generates an image (still image) by imaging, from above, an imaging target such as a component supplied by component supply unit 22 or a component mounted on board S, in addition to a mark attached to board S, and outputs the generated image to mounting control device 29. In addition, part camera 26 is disposed between component supply unit 22 and board conveyance unit 21, images, from below, a component held (picked up) by a nozzle to generate an image (still image), and outputs the generated image to mounting control device 29. Storage device 28 is a device such as an HDD that stores information on a mounting position of a processing program or a component, information on mounting history, and the like.

Built-in camera 27 is disposed in each mounting machine 20 so as to image the inside of each mounting machine 20 in an overhead manner and includes embedded ring buffer memory 27m (hereinafter, referred to as memory 27m) for storing the imaged image data, and control section 27c for controlling imaging processing or storage processing of the image data. Built-in camera 27 images, in a video, an operation situation of each unit such as board conveyance unit 21, component supply unit 22, and mounting unit 23, and stores the image data in memory 27m. In the present embodiment, built-in camera 27 includes two cameras of built-in camera 27f provided on a front side in mounting machine 20 and built-in camera 27r provided on a rear side in mounting machine 20. Built-in cameras 27f and 27r images, for example, a conveyance operation of board S by board conveyance unit 21, a supply operation of a component by component supply unit 22, a collection operation of a component by mounting unit 23, a movement operation of head 23a, a mounting operation of a component to board S, and the like. Memory 27m is configured as, for example, a ring buffer having multiple storage regions, and continuously stores frame images configuring a video in the multiple storage regions at a predetermined frame rate. In addition, after the frame images are stored in all the storage regions, memory 27m sequentially stores the frame images while overwriting the oldest frame image with a new frame image.

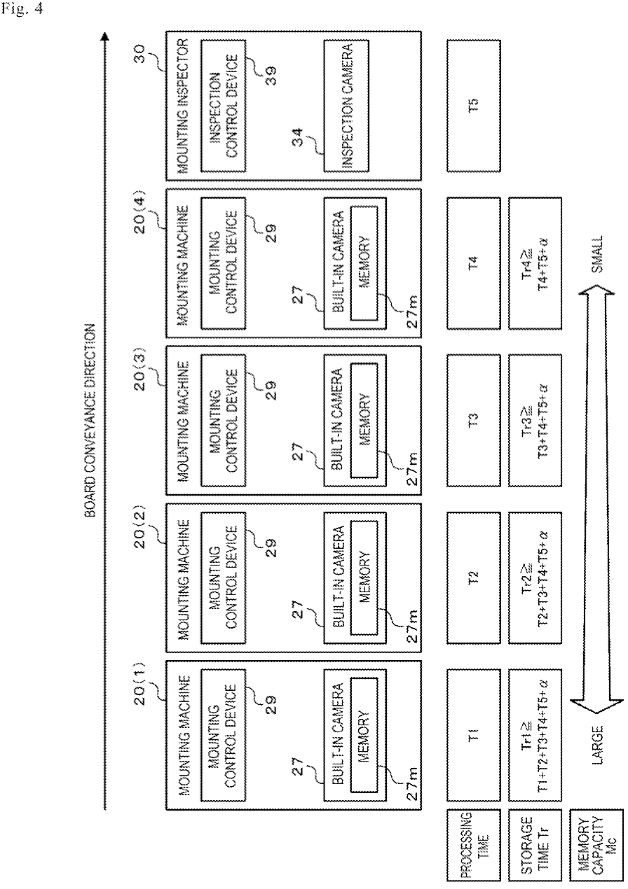

FIG. 4 is an explanatory diagram illustrating a capacity of memory 27m of built-in camera 27 provided in each mounting machine 20. Here, for example, it is assumed that processing times for mounting machines 20(1), 20(2), 20(3), and 20(4) arranged in this order along a conveyance direction to mount components necessary for boards S are respectively T1, T2, T3, and T4, and processing time for mounting inspector 30 to inspect boards S is T5. It is an object of the present embodiment to output image data during mounting process of board S for which inspection abnormality has occurred to the outside such that an operator can check the image data after an inspection process of the board S. Accordingly, at the time when the inspection process of board S is completed, it is necessary that other image data is not overwritten on the image data in memory 27m during the mounting process of board S. For example, when memory 27m of built-in camera 27 sets a time during which an image is to be stored (held) in a ring buffer as storage time Tr, storage time Tr1 of first mounting machine 20(1) may be, for example, a time greater than or equal to a time (T1 + T2 + T3 + T4 + T5 + a) obtained by adding a slight margin a to the sum of the respective processing times T1 to T5. Margin a is determined in consideration of a time during which a gist of an inspection abnormality is output from mounting inspector 30 to each mounting machine 20, a time necessary for mounting control device 29 or control section 27c of built-in camera 27 that has received the gist to output image data to the outside, and the like. Likewise, storage time Tr2 of second mounting machine 20(2) may be a time greater than or equal to a time (T2 + T3 + T4 + T5 + a). Storage time Tr3 of third mounting machine 20(3) may be a time greater than or equal to a time (T3 + T4 + T5 + a). Storage time Tr4 of fourth mounting machine 20(4) may be a time greater than or equal to a time (T4 + T5 + a). As described above, storage times Tr1 to Tr4 are long for mounting machine 20 whose processing order is earlier. In addition, memory capacity Mc of memory 27m of each built-in camera 27 in each of mounting machines 20(1) to 20(4) is determined to secure storage times Tr1 to Tr4. In the present embodiment, memory 27m of each built-in camera 27 has memory capacity Mc corresponding to storage times Tr1 to Tr4, respectively. Accordingly, memory capacity Mc of memory 27m of built-in camera 27 becomes mounting machines 20(1), 20(2), 20(3), and 20(4) in descending order. In other words, memory capacity Mc of memory 27m of built-in camera 27 tends to be reduced for mounting machine 20 whose processing order is later.

Mounting control device 29 is configured with a CPU, a ROM, and a RAM, which are well known, and the like. Mounting control device 29 outputs drive signals to board conveyance unit 21, component supply unit 22, mounting unit 23, and the like. Images from mark camera 25 and part camera 26 are input to mounting control device 29. Mounting control device 29 processes an image of board S imaged by mark camera 25, recognizes various marks affixed to board S, thereby recognizing identification information (board ID) such as a serial number of board S. In addition, mounting control device 29 determines whether a component is picked up by a nozzle based on the image captured by part camera 26, or determines a pick-up posture of the component. In addition, an image from built-in camera 27 is input to mounting control device 29 as necessary. Mounting control device 29 can store an image from built-in camera 27 in storage device 28 or output the image to management device 40.

As illustrated in FIG. 3, mounting inspector 30 includes board conveyance unit 32, inspection camera 34, camera moving device 36, storage device 38, and inspection control device 39. Board conveyance unit 32 has the same configuration as board conveyance unit 21 of mounting machine 20. Inspection camera 34 captures an inspection image from above board S on which components are mounted. Camera moving device 36 moves inspection camera 34 in the XY-directions and has the same configuration as head movement section 23b of mounting machine 20. Storage device 38 is a device such as an HDD that stores information such as a processing program and an inspection result.

Inspection control device 39 is configured with a CPU, a ROM, and a RAM, which are well known, and the like, and controls entirety of mounting inspector 30. Inspection control device 39 outputs drive signals to board conveyance unit 32 and camera moving device 36, and outputs an imaging signal to inspection camera 34. In addition, inspection control device 39 receives an inspection image from inspection camera 34, processes the image, and inspects a mounting state of a component. In addition, inspection control device 39 is communicably connected to mounting control device 29 and management control device 42 of management device 40 via LAN 18 and can output an inspection situation, information on an inspection result, an inspection image, and the like.

As illustrated in FIG. 3, management device 40 includes management control device 42, storage device 44, input device 46, and display 48. Management control device 42 is configured with a CPU, a ROM, and a RAM, which are well known, and the like. Storage device 44 is a device such as an HDD that stores various types of information such as a processing program. Input device 46 includes a keyboard, a mouse, and the like for an operator to input various commands. Display 48 is a liquid crystal display device that displays various types of information. In addition, storage device 44 stores a production program. The production program defines a component type and a mounting order of each component to be mounted on board S, a mounting position, information of component supply unit 22 that supplies each component, information of a nozzle for picking up each component, information as to which mounting machine 20 each component is to be mounted on, information of the number of boards S to be produced, and the like. Management control device 42 is communicably connected to mounting control device 29 via LAN 18, and receives information on a mounting situation from mounting control device 29 or transmits a production program to mounting control device 29. In addition, management control device 42 is communicably connected to inspection control device 39 via LAN 18, and receives information or the like output from inspection control device 39, or transmits information of board S of an inspection target to inspection control device 39. In addition to this, management control device 42 is communicably connected to each control device (not illustrated) of printer 12 and print inspector 14 via LAN 18, receives information on a work situation from each device, or transmits a work instruction.

The following describes a mounting process of a component onto board S and an inspection process of board S on which components are mounted, as an operation of component mounting system 10 configured in this way. In the mounting process, mounting control device 29 first causes board conveyance unit 21 to carry in and hold board S to a predetermined position. Next, mounting control device 29 causes component supply unit 22 to supply a component to a component supply position, causes mounting unit 23 to move head 23a above the component supply position, and causes a nozzle to pick up the component. Subsequently, mounting control device 29 causes mounting unit 23 to move head 23a above part camera 26, such that part camera 26 images the component picked up by the nozzle. Mounting control device 29 processes the captured image to correct a target mounting position of the component such that a positional deviation of the component is canceled, and then causes mounting unit 23 to move head 23a above board S to mount the component at the target mounting position. When mounting of a necessary component is completed, mounting control device 29 causes board conveyance unit 21 to cancel holding of board S and causes board S to be conveyed to the outside of the device. Mounting control device 29 stores identification information of board S, and information such as date and time of carrying in and out of board S, types and the number of mounted components, and a mounting position of a component in storage device 28 as mounting history information. Mounting control device 29 may receive the mounting history information from mounting control device 29 of mounting machine 20 on an upstream side and store information of components that have been mounted on carried-in board S.

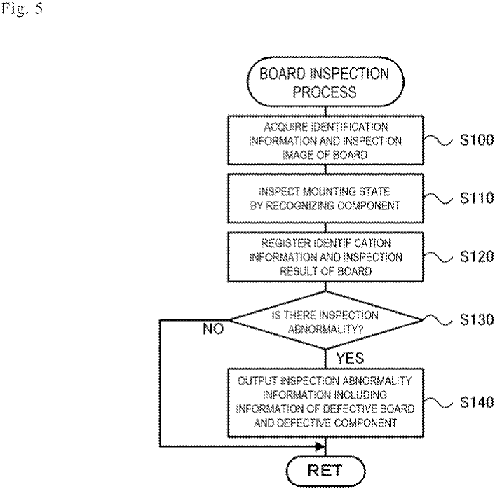

During the mounting process, built-in camera 27 images the operation situation of each unit in a video and stores the image data in memory 27m. For example, built-in camera 27 starts imaging with built-in camera 27 when first board S for which production is instructed by a production program is carried in, and ends the imaging with built-in camera 27 when last board S is carried out. Control section 27c adds date and time information to the captured image data and stores the date and time information in memory 27m. When board S on which components are mounted in this way is carried into mounting inspector 30, mounting inspector 30 performs an inspection process. FIG. 5 is a flowchart illustrating an example of a board inspection process.

In the board inspection process, inspection control device 39 acquires identification information and an inspection image of board S (S100). Inspection control device 39 acquires an image of board S captured by inspection camera 34 as an inspection image. In addition, inspection control device 39 may acquire the identification information of board S by communicating with mounting control device 29 or management device 40 adjacent thereto on an upstream side or may acquire the identification information recognized from the image of board S captured by inspection camera 34. Next, inspection control device 39 recognizes a component from the inspection image to inspect a mounting state (S110) and registers the identification information and the inspection result of board S in storage device 38 (S120). In S110, inspection control device 39 measures, for example, a deviation of a mounting position or a mounting angle of the component, inspects whether the measured deviation amount (a positional deviation or an angular deviation) is within a reference value, and also inspects whether the component is chipped or missing. In S120, when there is no inspection abnormality, inspection control device 39 registers a measurement result and a gist of inspection normality, and when there is an inspection abnormality, and inspection control device 39 registers the measurement result, the gist of an inspection abnormality, an error code indicating a type of the abnormality, and the like. Inspection control device 39 may register an inspection image when there is an inspection abnormality or may register an inspection image regardless of presence or absence of the inspection abnormality. Alternatively, inspection control device 39 may register only presence or absence of an inspection abnormality as an inspection result.

Next, inspection control device 39 determines whether there is an inspection abnormality in board S inspected this time (S130) and ends the board inspection process as it is when there is no inspection abnormality. Meanwhile, when it is determined that there is an inspection abnormality in board S that has been inspected this time, that is, board S that has been inspected this time is a defective board on which there are defective components in the mounted component, inspection control device 39 outputs inspection abnormality information including information that can specify the defective board and the defective component (S140), and ends the board inspection process. The inspection abnormality information includes identification information of a defective board, a component type and a mounting position of the defective component, an error code, and the like. The inspection abnormality information is output to each mounting machine 20 and management device 40 via LAN 18. The inspection abnormality information may be output from management device 40 to each mounting machine 20.

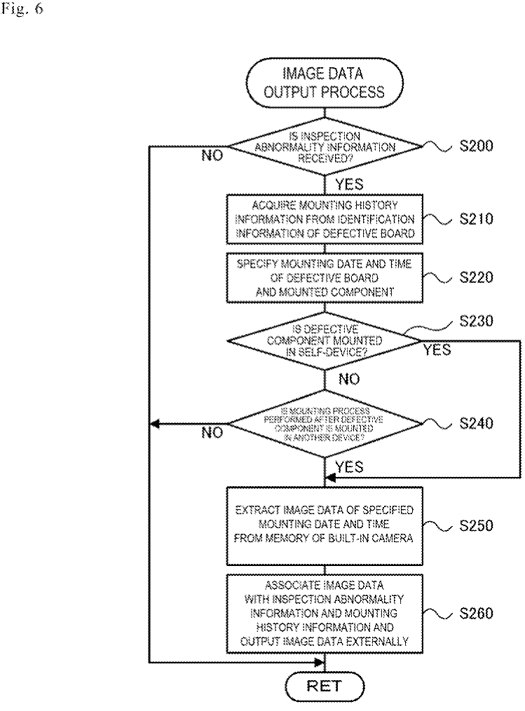

A process for outputting image data from memory 27m of built-in camera 27 included in each mounting machine 20 will be described. FIG. 6 is a flowchart illustrating an example of an image data output process. The image data output process is performed by, for example, mounting control device 29.

In the image data output process, mounting control device 29 determines whether inspection abnormality information output from mounting inspector 30 is received (S200), and ends the image data output process as it is when it is determined that the inspection abnormality information is not received. Meanwhile, when it is determined that the inspection abnormality information is received, mounting control device 29 acquires mounting history information of board S stored in storage device 28 based on identification information of a defective board included in the inspection abnormality information (S210), and specifies information of mounting date and time such as carrying-in date and time and carrying-out date and time of board S, and information (a component type, a mounting position, and the like) of a component mounted on the self-device based on the mounting history information (S220). Next, mounting control device 29 determines whether a defective component is mounted by the self-device based on the component type and the mounting position of the defective component included in the inspection abnormality information and information of the component specified in S220 (S230), and whether a mounting process of another component onto a defective board is performed by the self-device after a defective component is mounted in another device (S240). When information of the component mounted on carried-in board S is stored in storage device 28, mounting control device 29 performs determination of step S240 based on whether there is a defective component among the mounted components when board S (a defective board) is carried in the self-device. Alternatively, when a production program includes information as to which mounting machine 20 each component is to be mounted on, mounting control device 29 may perform the determination of S240 based on the information.

When it is determined that the defective component is mounted by the self-device or the mounting process is performed by the self-device after the defective component is mounted in another device, mounting control device 29 outputs an instruction to built-in camera 27 of the self-device such that image data of date and time corresponding to the mounting date and time specified in S210 are extracted from memory 27m (S250). Control section 27c received an instruction extracts image data corresponding to the instructed date and time from memory 27m based on the date and time information appended to the image data. When the image data is extracted from memory 27m, mounting control device 29 outputs the image data to the outside in association with the inspection abnormality information and the mounting history information acquired in step S210 (S260), and ends the image data output process. Mounting control device 29 outputs the extracted image data, the inspection abnormality information, and the mounting history information to, for example, management device 40, and management device 40 stores the extracted image data, the inspection abnormality information, and the mounting history information in storage device 44. Accordingly, an operator can investigate presence or absence of an abnormality during the mounting process and a cause of abnormality while displaying a video during the mounting process of the defective board on display 48.

When it is determined in S230 and S240 that, the defective component is not mounted by the self-device and the mounting process has not been performed by the self-device after the defective component has been mounted by another device, that is, the mounting process for the defective board has been performed before the defective component is mounted, mounting control device 29 skips S250 and S260 and ends the image data output process. In the present embodiment, when a defective component is mounted by the self-device, image data is output to the outside, and also, even when the mounting process is performed by the self-device after a defective component is mounted by another device, the image data is output to the outside. This is for a cause to be investigated because, when the mounting process is performed by the self-device, a component of a mounting target may come into contact with a component that has been mounted by another device, and when board S is conveyed and held and when board S is released from holding, a large impact is given and positional deviation or falling of the component that has been mounted by another device may occur, resulting in defects.

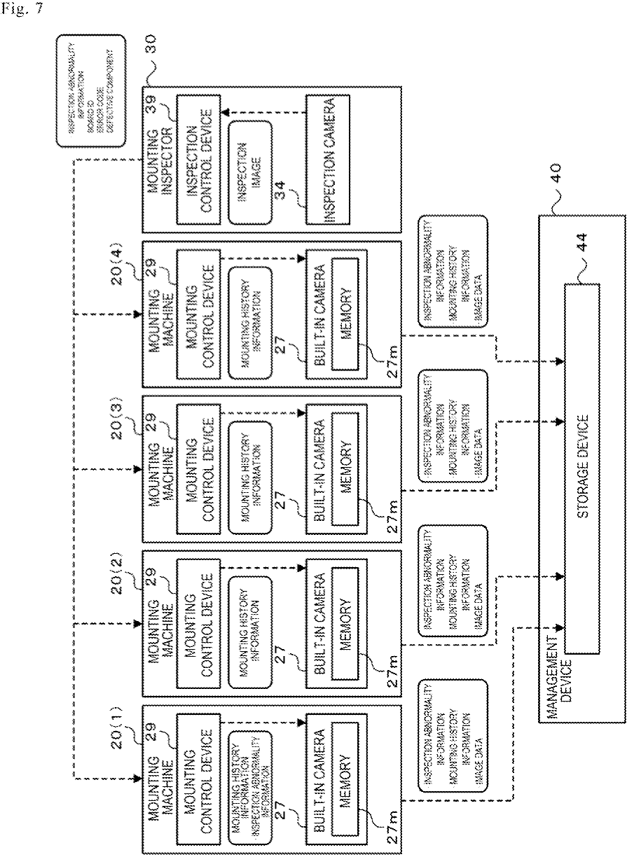

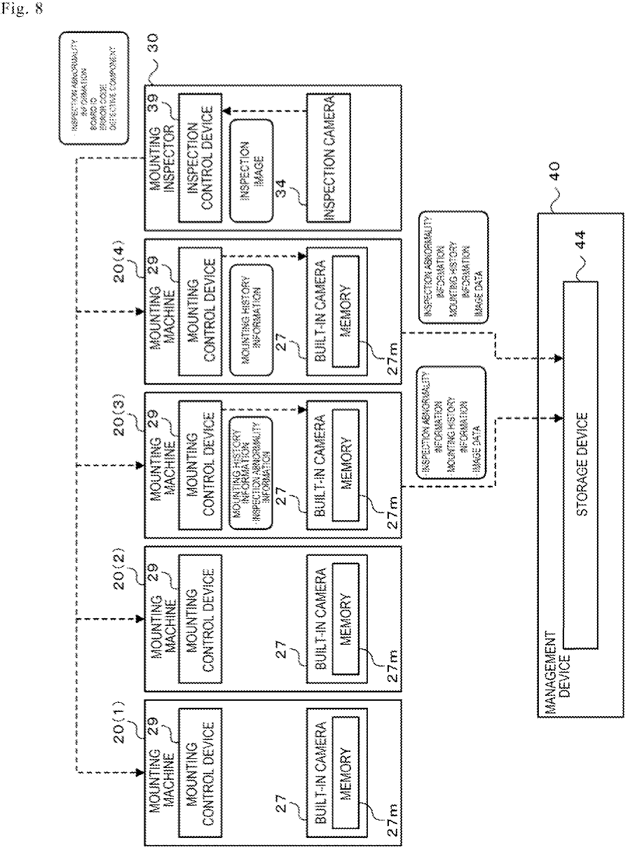

FIGS. 7 and 8 are explanatory diagrams illustrating a state in which image data is output from each built-in camera 27. FIG. 7 exemplifies a case where a mounting process of a defective component onto a defective board is performed by first mounting machine 20(1). In this case, when inspection abnormality information is received, mounting machine 20(1) determines that a defective component is mounted by the self-device, and mounting machines 20(2) to 20(4) determine that the mounting process has been performed after the defective component was mounted by another device. Accordingly, each of mounting machines 20(1) to 20(4) extracts image data during a mounting process of a defective board from memory 27m, associates the inspection abnormality information and the mounting history information with the image data, and externally outputs the image data to management device 40.

FIG. 8 exemplifies a case where a mounting process of a defective component onto a defective board is performed by third mounting machine 20(3). In this case, when inspection abnormality information is received, mounting machines 20(1) and 20(2) determine that the mounting process for the defective board has been performed before mounting of the defective component, mounting machine 20(3) determines that the defective component has been mounted by the self-device, and mounting machine 20(4) determines that the mounting process has been performed after mounting of the defective component by another device. Accordingly, mounting machines 20(3) and 20(4) extract image data during the mounting process of the defective board from memory 27m, associate the inspection abnormality information and mounting history information with the image data, and externally output the image data to management device 40. However, since mounting machines 20(1) and 20(2) do not perform the extraction or the external output of the image data, it is possible to prevent the image data or the like unnecessary for investigation of a cause of defect from being output to the outside.

A correspondence relationship between a configuration element of the present embodiment and a configuration element of the present disclosure will be clarified. Board conveyance unit 21, component supply unit 22, and mounting unit 23 of the present embodiment correspond to units for a mounting process, mounting machine 20 corresponds to a mounting machine, mounting inspector 30 corresponds to an inspector, built-in camera 27 corresponds to a camera, memory 27m corresponds to a memory, and mounting control device 29 and control section 27c correspond to data output sections.

In component mounting system 10 of the present embodiment described above, built-in camera 27 images, in a video, operations of board conveyance unit 21, component supply unit 22, and mounting unit 23 included in mounting machine 20 during a mounting process, and stores the image data in memory 27m. Then, based on inspection abnormality information output from mounting inspector 30, image data during a mounting process of a defective board is extracted from image data in memory 27m of built-in camera 27 and output to the outside. Accordingly, it is possible to reduce labor for an operator or the like to search a memory for image data during a mounting process of a defective board. In addition, an operator can investigate a cause while checking an operation situation of each unit in a video. Therefore, the operator can easily investigate a cause of abnormality.

Since inspection abnormality information includes information on an error code or a defective component detected in an inspection process, and the inspection abnormality information and image data are associated with each other and output, an operator can more easily investigate a cause of abnormality while referring to the inspection abnormality information. In addition, since mounting machine 20 does not output image data from memory 27m before a defective component is mounted, it is possible to prevent an operator or the like from investigating unnecessary image data.

Memory 27m serving as a ring buffer is configured to have a longer storage time than a processing time required from the start of a first mounting process of one board S to the end of the inspection process. Accordingly, before the image data stored in memory 27m is overwritten, necessary image data can be appropriately output to the outside. In addition, since the later the processing order of mounting machine 20, the smaller the memory capacity Mc of memory 27m, memory capacity Mc can be optimized to prevent unnecessary image data from being accumulated and to reduce costs.

The present disclosure is not limited to the embodiments described above, and it is needless to say that various forms can be implemented within the technical scope of the present disclosure.

For example, in the embodiment described above, the later the processing order of mounting machine 20, the smaller the memory capacity Mc of memory 27m of built-in camera 27, but the present disclosure is not limited thereto, and memory capacities Mc of respective mounting machines 20 may be the same as each other. In addition, although memory 27m is a ring buffer, the present disclosure is not limited thereto, and a buffer other than the ring buffer may be used therefor. In addition, although built-in camera 27 stores image data in embedded memory 27m, the present disclosure is not limited thereto, and the image data may be stored in a memory other than memory 27m. Even when image data is stored in any memory, the image data may be extracted from the memory and output to the outside based on inspection abnormality information.

In the embodiment described above, two built-in cameras 27f and 27r are exemplified as built-in camera 27, but the present invention is not limited thereto, and three or more built-in cameras 27 may be arranged in each mounting machine 20, and only one camera 27 may be disposed in each mounting machine 20. In addition, although image data extracted from memory 27m of built-in camera 27 is externally output to management device 40 (storage device 44), the present invention is not limited thereto, and the image data may be externally output to a cloud server or the like via a network.

In the embodiment described above, image data extracted from memory 27m is output to the outside in association with inspection abnormality information and mounting history information, but the present invention is not limited thereto, and the image data may be output to the outside in association with information other than this and may be output to the outside in association with only the inspection abnormality information. In addition, image data may be output to the outside in association with an inspection image used in mounting inspector 30 and may be output to the outside in association with an inspection abnormality method and the inspection image. Alternatively, the extracted image data may be output to the outside without being associated with other information. In addition, a device (for example, management device 40 or the like) received the externally output image data may store the image data in association with other information, an inspection image, and the like.

In the embodiment described above, image data is output to the outside from memory 27m by targeting mounting machine 20 in which a defective component is mounted and mounting machine 20 on a downstream side of mounting machine 20, but the present invention is not limited thereto, and the image data may be output to the outside from memory 27m by targeting all mounting machines 20.

In the embodiment described above, component mounting system 10 includes multiple mounting machines 20 and mounting inspector 30, but the present invention is not limited thereto, and component mounting system 10 may include one mounting machine 20 and one mounting inspector 30. In addition, although mounting inspector 30 dedicated to inspection is exemplified as an inspector, the present invention is not limited thereto, and mounting machine 20 may also serve as the inspector. For example, mounting machine 20 on a downstream side performs a mounting process after performing an inspection process by using an image of board S captured by mark camera 25 when board S is received, and outputs abnormality information when an abnormality is detected in the inspection process. In addition, mounting machine 20 on an upstream side may extract image data based on the abnormality information and output the extracted image data to the outside.

A component mounting system of the present disclosure may be configured as follows. For example, in the component mounting system of the present disclosure, the abnormality information may include information on content of an abnormality detected in the inspection process, and the data output section may output at least one of the image of the board used in the inspection process or the abnormality information, and the image data extracted from the memory in association with each other. Accordingly, a cause can be investigated by using image data during a mounting process of a defective board with reference to at least one of an image of a board used in the inspection process or information on content of an abnormality, and thereby, the cause can be investigated more easily.

In the component mounting system of the present disclosure, multiple mounting machines configured to sequentially deliver the board to perform the mounting process may be provided, the abnormality information may include information capable of specifying a defective component having an abnormality detected from the defective board, and the data output section may extract the image data from the memory by targeting a mounting machine that has performed the mounting process of the defective component on the defective board and a mounting machine that has performed the mounting process on the defective board later than the mounting machine among the multiple mounting machines and may output the image data. Accordingly, it is possible to investigate a cause of abnormality when a defective component is mounted and a cause of abnormality when a defective board is mounted after the defective component is mounted. In addition, since image data is not output from a memory of a camera that images the inside of a mounting machine other than a target, it is possible to prevent an operator or the like from investigating unnecessary image data.

In the component mounting system of the present disclosure, multiple mounting machines configured to sequentially deliver the board to perform the mounting process may be provided, and the memory may be a ring buffer and configured such that a storage time of the image data is longer than a processing time required from a start of the mounting process by a mounting machine whose processing order of the mounting process is first among the multiple mounting machines to an end of the inspection process, for the one board. Accordingly, it is possible to output image data necessary for investigating a cause of abnormality to the outside before the image data stored in a memory is overwritten while preventing unnecessary image data from being accumulated in the memory.

In the component mounting system of the present disclosure, multiple mounting machines configured to sequentially deliver the board to perform the mounting process may be provided, and the memory may be a ring buffer and configured such that a memory capacity tends to be reduced for the camera for imaging an inside of a mounting machine that is later in a processing order of the mounting process among the multiple mounting machines. Accordingly, it is possible to optimize a memory capacity and reduce costs while preventing unnecessary image data from being accumulated in a memory.

### INDUSTRIAL APPLICABILITY

The present disclosure can be used in a technical field or the like of a mounting process of a component.

### REFERENCE SIGNS LIST

10: component mounting system, 12: printer, 14: print inspector, 18: LAN, 20, 20(1) to 20(4) : mounting machine, 21, 32: board conveyance unit, 22: component supply unit, 23: mounting unit, 23a: head, 23b: head movement section, 25: mark camera, 26: part camera, 27, 27f, 27r: built-in camera, 27c: control section, 27m: memory (ring buffer memory), 28: storage device, 29: mounting control device, 30: mounting inspector, 32: board conveyance unit, 34: inspection camera, 36: camera moving device, 39: inspection control device, 40: management device, 42: management control device, 44: storage device, 46: input device, 48: display, S: board.

1. A component mounting system comprising:
a mounting machine configured to perform a mounting process of a component on a board by an operation of a unit for the mounting process;
an inspector configured to perform an inspection process by using an image of the board after the mounting process and output abnormality information capable of specifying a defective board having an abnormality detected in the inspection process;
a camera configured to image the operation of the unit in the mounting machine during the mounting process in a video to store image data in a memory; and
a data output section configured to extract image data during the mounting process of the defective board from the memory based on the abnormality information and output the image data to an outside.

2. The component mounting system according to claim 1, wherein
the abnormality information includes information on content of an abnormality detected in the inspection process, and
the data output section outputs at least one of the image of the board used in the inspection process or the abnormality information, and the image data extracted from the memory in association with each other.

3. The component mounting system according to claim 1, wherein
multiple mounting machines configured to sequentially deliver the board to perform the mounting process are provided,
the abnormality information includes information capable of specifying a defective component having an abnormality detected from the defective board, and
the data output section extracts the image data from the memory by targeting a mounting machine that has performed the mounting process of the defective component on the defective board and a mounting machine that has performed the mounting process on the defective board later than the mounting machine among the multiple mounting machines and outputs the image data.

4. The component mounting system according to claim 1, wherein
multiple mounting machines configured to sequentially deliver the board to perform the mounting process are provided, and
the memory is a ring buffer and configured such that a storage time of the image data is longer than a processing time required from a start of the mounting process by a mounting machine whose processing order of the mounting process is first among the multiple mounting machines to an end of the inspection process, for the one board.

5. The component mounting system according to claim 1, wherein
multiple mounting machines configured to sequentially deliver the board to perform the mounting process are provided, and
the memory is a ring buffer and configured such that a memory capacity tends to be reduced for the camera for imaging an inside of a mounting machine that is later in a processing order of the mounting process among the multiple mounting machines.
